(19) United States
(12) Patent Application Publication
(10) Pub. No.: US 2007/0072399 A1
(43) Pub. Date: Mar. 29, 2007

(54) Semiconductor Devices Having Epitaxial Layers with Suppressed Lateral Growth and Related Methods of Manufacturing Such Devices

(75) Inventors: Young-Pil Kim, Gyeonggi-do (KR); Jin-Bum Kim, Seoul (KR); Jun-Ho Lee, Seoul (KR); Hyung-ik Lee, Chungcheongbuk-do (KR); Hion-Suck Baik, Chungcheongnam-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/530,498

(22) Filed: Sep. 11, 2006

(30) Foreign Application Priority Data
Sep. 26, 2005 (KR) 10-2005-0089475

(51) Int. Cl. H01L 21/20; H01L 21/00; H01L 21/36; H01L 31/20

(52) U.S. Cl. 438/481; 438/482; 438/483

(57) ABSTRACT

Semiconductor devices are provided having a selective epitaxial growth layer that exhibits suppressed lateral growth. These semiconductor devices may include a semiconductor substrate having a silicon region, and an epitaxial growth layer formed on the silicon region. The epitaxial growth layer may comprise alternatively stacked silicon and silicon germanium epitaxial layers. The silicon germanium epitaxial layer may be thinner than the silicon epitaxial layers.

### CROSS-REFERENCE TO RELATED PATENT APPLICATION

This application claims priority under 35 U.S.C. § 119 from Korean Patent Application No. 2005-0089475, filed on Sep. 26, 2005, the disclosure of which is hereby incorporated by reference herein as if set forth in its entirety.

### FIELD OF THE INVENTION

The present invention relates to semiconductor devices and, more particularly, to semiconductor devices having selective epitaxial growth layers and methods of manufacturing such semiconductor devices.

### BACKGROUND

As the integration density of semiconductor devices increases, the dimensions, such as channel lengths, of MOS transistors that are included in such devices are being decreased so that many more elements may be integrated into a limited space. If the channel length of a MOS transistor is decreased, high integration of a circuit can be achieved. However, the decreased channel length may result in short channel effects such as Drain Induced Barrier Lowering (DIBL), hot carrier effect and punchthrough, each of which can cause abnormal operation of the MOS transistor.

One way of reducing and/or preventing the short channel effect is to form the MOS transistor to have shallow source/drain regions. However, this technique may require implanting impurity ions at a shallow depth, and may cause high leakage current resulting from junction pitting when forming an ohmic contact layer or a metal interconnect on the source/drain regions.

In order to reduce such effects, an elevated source/drain technique has been used, in which a silicon substrate in which the source/drain regions are formed is grown epitaxially, and impurity ions are implanted into this epitaxial layer. This technique is described, for example, in U.S. Pat. No. 6,297,109. The elevated source/drain can maintain a shallow junction with a substrate, and simultaneously secure a sufficient junction area since the source/drain protrudes above the substrate. As a result, ions may be more easily implanted to form the source/drain regions, and junction pitting may be reduced and/or avoided when forming an ohmic contact layer or a metal interconnect, thereby reducing the junction leakage current.

However, as the silicon of the source/drain is grown epitaxially, it may grow both laterally and vertically at similar rates. Accordingly, as shown in FIG. 1, when the height “h” of a silicon epitaxial source/drain region 20 is increased, the width “l” thereof is also increased. With highly integrated devices, this increased lateral growth can produce a bridge B with an adjacent source/drain region. In FIG. 1, reference numeral 10 denotes a silicon substrate, reference numeral 15 denotes a device isolation layer, and reference numeral 20 denotes an epitaxially grown silicon source/drain region.

FIGS. 2A through 2C are Scanning Electron Microscope (SEM) images showing linewidth variation as a function of the height of the silicon epitaxial growth layer. In particular, FIG. 2A shows the silicon epitaxial source/drain region grown to a height of 400 Å, FIG. 2B shows the silicon epitaxial source/drain region grown to a height of 600 Å, and FIG. 2C shows the silicon epitaxial source/drain region grown to a height of 800 Å. As can be seen from FIGS. 2A-2C, as the height of the silicon epitaxial source/drain region increases, so does the linewidth. As can be seen in FIG. 2C, when the height of silicon epitaxial source/drain region is increased beyond a certain point (in this example, 800 Å), the gap between adjacent silicon epitaxial source/drain regions may disappear, as shown in the circled region of FIG. 2C.

Therefore, if the silicon epitaxial source/drain region is higher than a certain height (which is a function of, among other things, the integration density of the device), a bridge may be formed. However, when the height of the epitaxial source/drain region is restricted, it may be difficult to provide an elevated source/drain region having a sufficient junction depth.

### SUMMARY

Embodiments of the present invention provide semiconductor devices having selective epitaxial growth layers with suppressed lateral growth. As a result, semiconductor devices according to certain embodiments of the present invention may have epitaxial source/drain regions with a sufficient height and high integration densities.

According to certain embodiments of the present invention, semiconductor devices are provided that include a semiconductor substrate having a silicon region and an epitaxial growth layer on the silicon region. The epitaxial growth layer may comprise a first silicon epitaxial layer and a second silicon epitaxial layer that are alternatively stacked with a first epitaxial layer containing a germanium component and a second epitaxial layer containing a germanium component. The first and second epitaxial layers containing a germanium component may comprise first and second silicon germanium epitaxial layers.

In certain embodiments, the combined thickness of the first and second silicon germanium epitaxial layers may be less than a combined thickness of the first and second silicon epitaxial layers. In other embodiments, the combined thickness of the first and second silicon germanium epitaxial layers may be approximately equal to a combined thickness of the first and second silicon epitaxial layers. The thickness of each of the first and second silicon epitaxial layers and the first and second silicon germanium epitaxial layers may be between about 10˜300 Å, and the atomic germanium density of at least one of the first or second silicon germanium epitaxial layers may be between about 2˜40%.

In some embodiments, at least one of the first or second silicon germanium epitaxial layers is a graded silicon germanium epitaxial layer. The thickness of the graded silicon Germanium epitaxial layer may be between about 20˜500 Å. The germanium density of the graded silicon germanium epitaxial layer may either increase or decrease with the thickness of the graded silicon germanium epitaxial layer.

Pursuant to further embodiments of the present invention, semiconductor devices are provided that include a semiconductor substrate having a top surface and an epitaxial layer including a first silicon epitaxial layer on the semiconductor substrate. The epitaxial layer may further include a first silicon germanium epitaxial layer on the first silicon epitaxial layer, and a second silicon epitaxial layer on the first silicon germanium epitaxial layer. First and second source/drain regions may be provided in the epitaxial layer. The epitaxial layer may further include a second silicon germanium epitaxial layer either (1) between the semiconductor substrate and the first silicon epitaxial layer or (2) on the second silicon epitaxial layer.

The combined thickness of the first and second silicon germanium epitaxial layers may be less than a combined thickness of the first and second silicon epitaxial layers. The first silicon epitaxial layer and the first silicon germanium epitaxial layer may each have a thickness of between about 10˜300 Å. The atomic germanium density of the first silicon germanium epitaxial layer may be about 2˜40%. In other embodiments, the first silicon germanium epitaxial layer may be a graded silicon germanium epitaxial layer, and may have a thickness of between about 20˜500 Å.

Pursuant to still further embodiments of the present invention, methods of manufacturing semiconductor devices are provided in which a first silicon epitaxial layer is formed on a semiconductor substrate, a first epitaxial layer containing a germanium component is formed on the first silicon epitaxial layer, and a second silicon epitaxial layer is formed on the first epitaxial layer containing a germanium component. A second epitaxial layer containing a germanium component may be formed between the semiconductor substrate and the first silicon epitaxial layer or on the second silicon epitaxial layer.

### BRIEF DESCRIPTION OF THE DRAWINGS

The above and other features and advantages of the present invention will become more apparent by describing in detail exemplary embodiments thereof with reference to the attached drawings in which,

FIG. 1 is a cross-sectional diagram of a conventional semiconductor device that includes elevated silicon epitaxial source/drain regions;

FIGS. 2A through 2C are Scanning Electron Microscope (SEM) images of conventional semiconductor devices that include elevated silicon epitaxial source/drain regions having thicknesses of 400 Å, 600 Å and 800 Å, respectively;

FIG. 3 is a cross sectional diagram of a selective epitaxial growth layer according to embodiments of the present invention that includes multiple silicon and silicon germanium epitaxial layers;

FIG. 4 is a cross sectional diagram illustrating growth characteristics of the silicon germanium epitaxial layer;

FIG. 5 is an SEM image showing the growth characteristics of the silicon germanium epitaxial layer;

FIG. 6A is a cross sectional diagram illustrating the growth of the silicon epitaxial layer on the substrate and the growth of the silicon germanium epitaxial layer on the silicon epitaxial layer;

FIG. 6B is a cross sectional diagram illustrating the growth of the silicon germanium epitaxial layer on the substrate and the silicon epitaxial layer on the silicon germanium epitaxial layer;

FIG. 6C is a cross sectional diagram illustrating the growth of an epitaxial layer that includes multiple silicon and silicon germanium epitaxial layers;

FIG. 7A is an SEM image of the semiconductor device illustrated in FIG. 6A;

FIG. 7B is an SEM image of the semiconductor device illustrated in FIG, 6B;

FIG. 7C is an SEM image of the semiconductor device illustrated in FIG. 6C;

FIG. 8 is an SEM image showing the selective removal of the silicon germanium epitaxial layer from the epitaxial growth layer according to embodiments of the present invention;

FIG. 9 is a cross sectional diagram of the relatively thin epitaxial growth layer having silicon and silicon germanium epitaxial layers according to further embodiments of the present invention;

FIG. 10 is an SEM image of the selective epitaxial growth layer of FIG. 9;

FIGS. 11 and 12 are cross sectional diagrams of semiconductor devices having epitaxial growth layers that include graded silicon germanium epitaxial layers according to still further embodiments of the present invention;

FIG. 13 is a cross sectional diagram of a semiconductor device according to another embodiment of the present invention in which the lower-most layer of the epitaxial growth layer is a silicon germanium epitaxial layer; and

FIGS. 14A through 14D are cross sectional diagrams illustrating methods of manufacturing semiconductor devices having a selective epitaxial growth layer according to embodiments of the present invention.

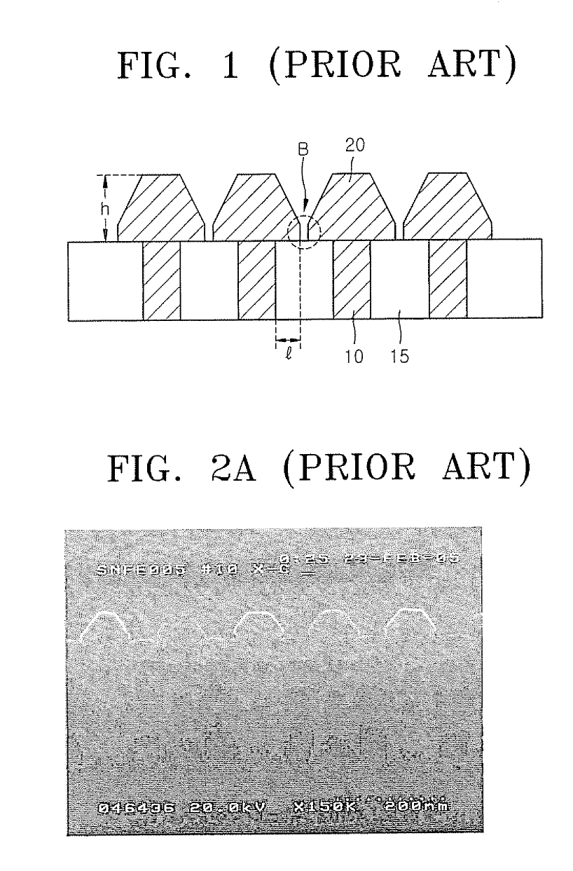

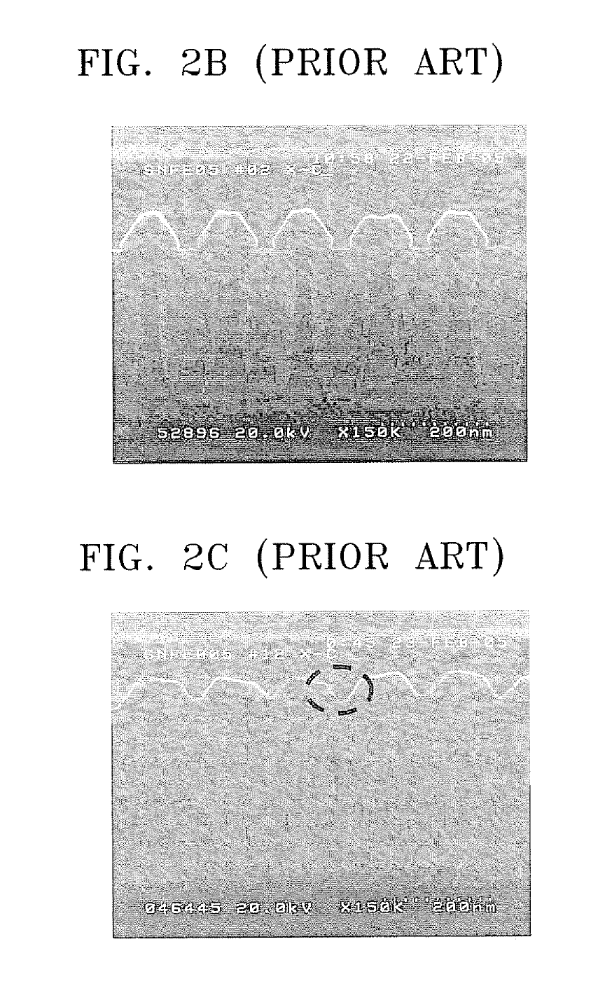

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures. Also, as used herein, “lateral” refers to a direction that is substantially orthogonal to a vertical direction.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, the regions illustrated in the figures are schematic in nature, and embodiments of the invention should not be construed as limited to the particular shapes of regions illustrated herein but are to include deviations in shapes that result, for example, from manufacturing.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this disclosure and the relevant art and will not be interpreted in an idealized or overly formal sense unless expressly so defined herein.

According to embodiments of the present invention, semiconductor devices are provided that include an epitaxial layer that may be used to form elevated source/drain regions. The epitaxial layer may include a plurality of layers that include germanium that may suppress the lateral growth of the epitaxial layer. By including at least one germanium-containing layer with the lateral growth suppressing ability (e.g., a silicon germanium epitaxial layer) in the multi-layer epitaxial layer, the lateral growth of the silicon epitaxial layer may be suppressed, and the occurrence of bridges between adjacent source/drain regions may be reduced and/or prevented. Therefore, a relatively large junction thickness (height) may be achieved even in highly integrated semiconductor devices.

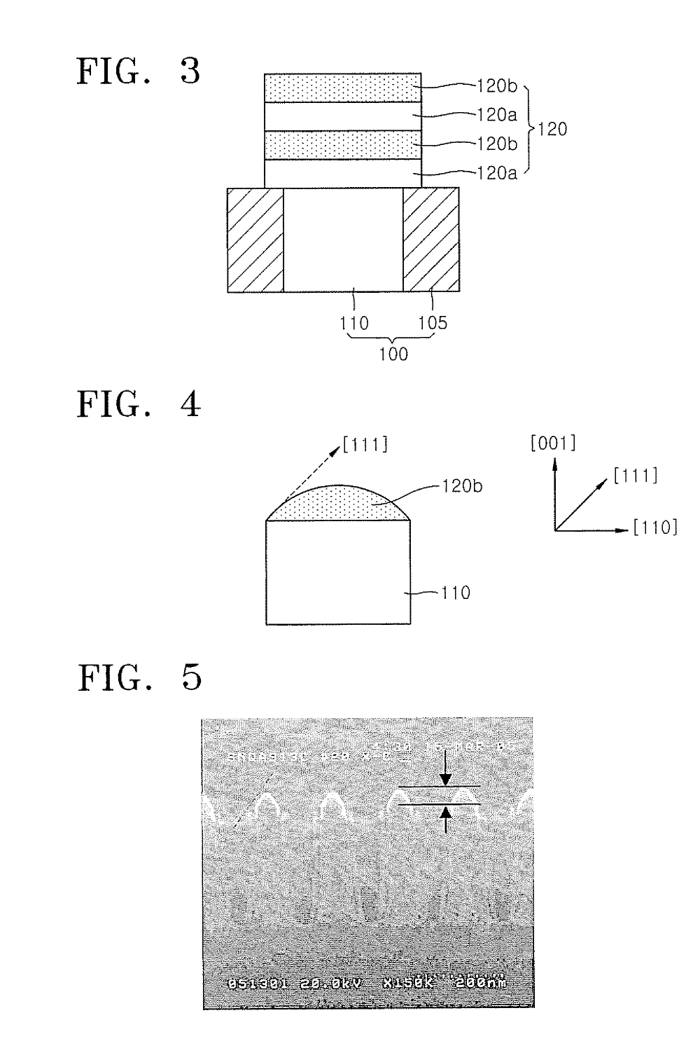

FIG. 3 is a cross sectional diagram of a multi-layer epitaxial growth layer according to certain embodiments of the present invention. As shown in FIG. 3, an epitaxial growth layer 120 is grown on a semiconductor substrate 100. The semiconductor substrate 100 includes a silicon containing region 110 and an insulating region 105. The epitaxial growth layer 120 is grown on the silicon containing region 110. The epitaxial growth layer 120 may be a stacked structure alternately repeating a silicon epitaxial layer 120a and a silicon germanium epitaxial layer (Siₓ,Ge_{y}) 120b two or more times. The silicon germanium epitaxial layers 120b may help reduce the overall lateral growth of the epitaxial layer 120.

The silicon epitaxial layer 120a grows laterally, i.e., in the [110] orientation, as well as vertically, i.e., in the [001] orientation, as described above. The silicon germanium layers 120b, on the other hand, grow in a diagonal direction, i.e., in the [111] orientation, but exhibit little or no growth in the lateral direction, i.e., in the [100] orientation, as shown in FIGS. 4 and 5. Moreover, the growth speed of the silicon germanium epitaxial layer in the diagonal direction is significantly slower than the growth speed of a silicon epitaxial layer. As shown herein, when silicon layers having high growth speed in both the vertical and lateral directions and silicon germanium layers that exhibit diagonal growth are alternately stacked, a multi-layer epitaxial layer of the desired height may be grown that has suppressed lateral growth.

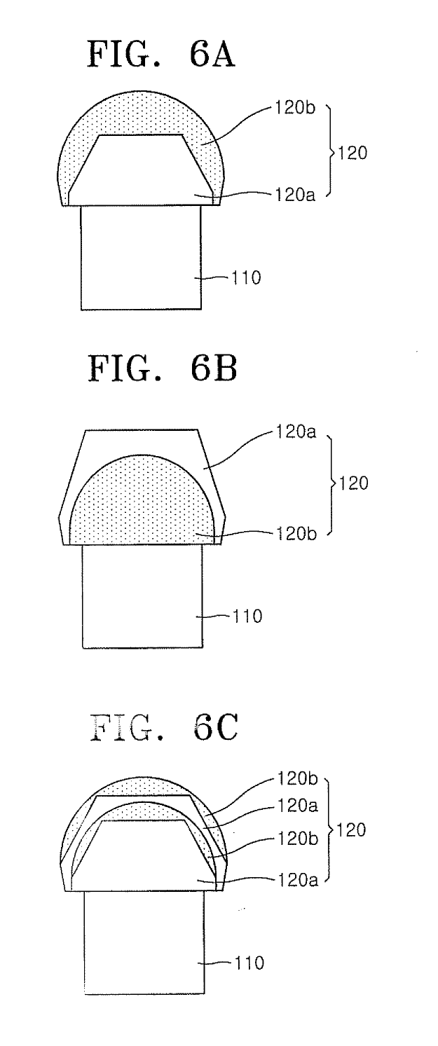

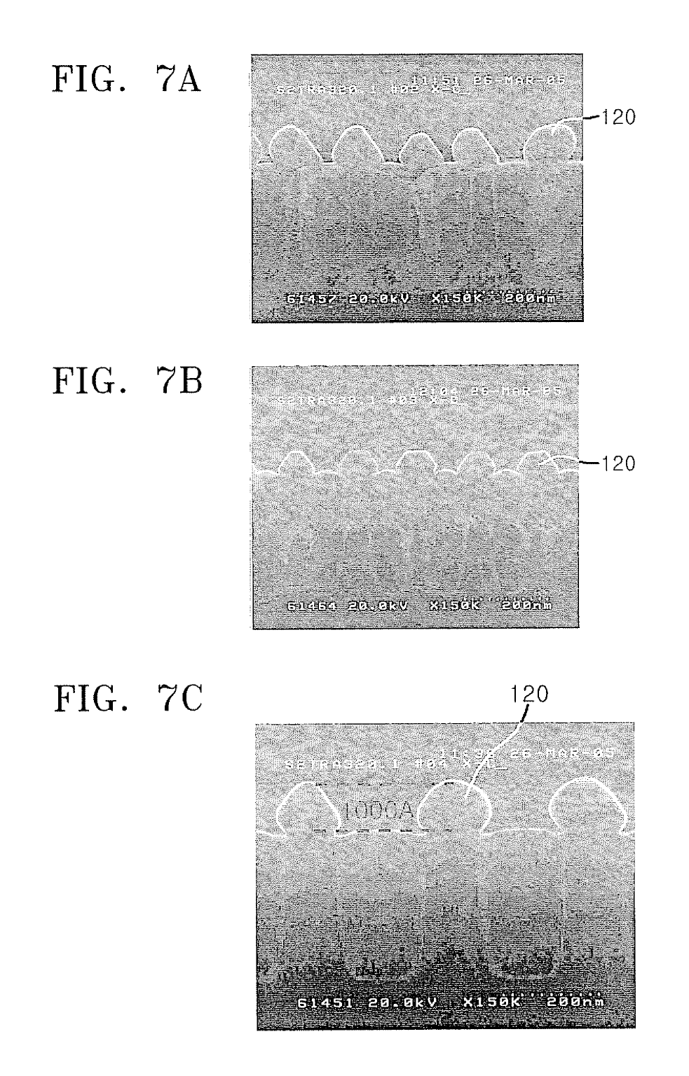

FIGS. 6A-6C and FIGS. 7A-7C illustrate how providing an epitaxial layer that includes multiple, alternatively stacked silicon epitaxial layers 120a and silicon germanium epitaxial layers 120a according to certain embodiments of the present invention may facilitate suppressing lateral growth.

FIG. 6A is a cross sectional diagram of a portion of a semiconductor device in which a silicon epitaxial layer 120a and a silicon germanium epitaxial layer 120b are sequentially grown on a silicon region 110 of a semiconductor substrate. It will be appreciated that the semiconductor substrate may comprise, for example, a conventional semiconductor substrate, a silicon-on-insulator semiconductor substrate or a silicon growth layer in a vertically stacked semiconductor device. As shown in FIG. 6A, the silicon germanium epitaxial layer 120b may have a mountain or convex shape in the [111]orientation on the upper surface of the silicon epitaxial layer 120a. This may not be favorable in view of uniformity. FIG. 7A is an SEM image of a semiconductor device that includes an epitaxial layer 120 that comprises a single silicon germanium epitaxial layer 120b stacked on a single silicon epitaxial layer 120a. As shown in FIG. 7A, the epitaxial growth layer 120 may have an uneven shape.

FIG. 6B is a cross sectional diagram of a portion of a semiconductor device in which a silicon germanium epitaxial layer 120b, and then a silicon epitaxial layer 120a, are consecutively grown on the silicon region 110 of a semiconductor substrate. FIG. 7B is an SEM image of the semiconductor device of FIG. 6B. Even if the silicon germanium epitaxial layer 120b and the silicon epitaxial layer 120a are formed under the same thickness conditions, the layers in FIG. 6B are thinner than the layers in FIG. 6A. That is, when the silicon germanium epitaxial layer 120b is formed first, the upward growth of the silicon germanium epitaxial layer 120b is restricted. Thus, the overall height of the epitaxial layer 120 in the device of FIG. 6B is lower than the overall height of the epitaxial layer 120 in the device of FIG. 6A. When the SEM images of FIGS. 7B and 7A are compared, the height of the epitaxial growth layer 120 shown in FIG. 7B is lower.

FIG. 6C is a cross-sectional diagram of a portion of a semiconductor device in which the epitaxial layer 120 comprises two silicon epitaxial layers 120a and two silicon germanium epitaxial layers 120b alternately stacked on the silicon region 110 of a semiconductor substrate. As shown in FIG. 6C, the silicon epitaxial layers 120a are relatively thin, and thus the lateral growth of the epitaxial layer 120 is suppressed. Thus, the epitaxial layer 120 of FIG. 6C may have a sufficient thickness without excessive lateral growth as a result of the silicon germanium layers 12b, and may exhibit good uniformity as a result of the silicon epitaxial layers 120a. FIG. 7C is an SEM image of a semiconductor device that includes an epitaxial growth layer 120 formed by alternatively stacking two 200 Angstrom silicon epitaxial layers 120a and two 200 Angstrom silicon germanium epitaxial layers 120b. As shown in FIG. 7C, an epitaxial growth layer 120 having-a total thickness of 800 Angstrom and relatively consistent dimensions was formed, and no bridges were generated between adjacent growth regions.

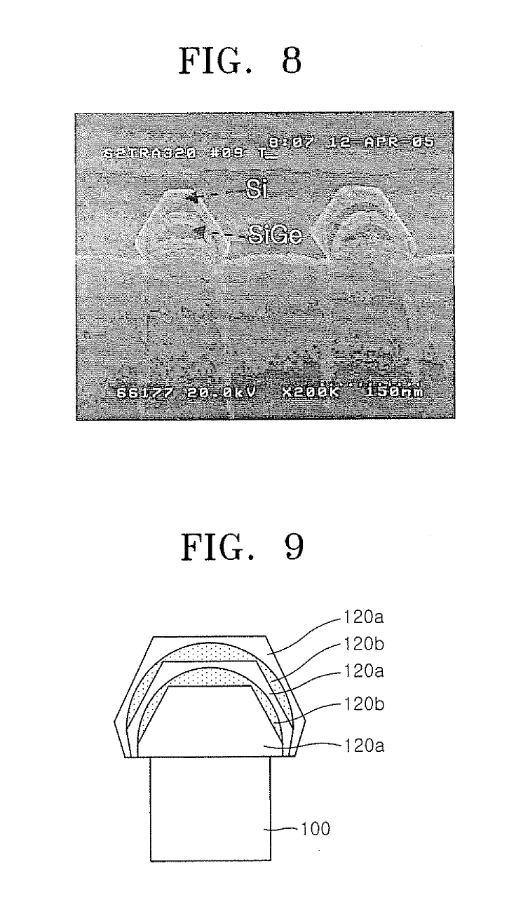

FIG. 8 is an SEM image showing the selective removal of the silicon germanium epitaxial layer from the epitaxial growth layer to clearly show stacking of two layers. Additionally, the silicon epitaxial layer and the silicon germanium epitaxial layer each have a thickness of 200 Angstrom, and the total thickness of the epitaxial growth layer is approximately 800 Angstrom. However, no bridges occur, unlike the conventional epitaxial growth layer.

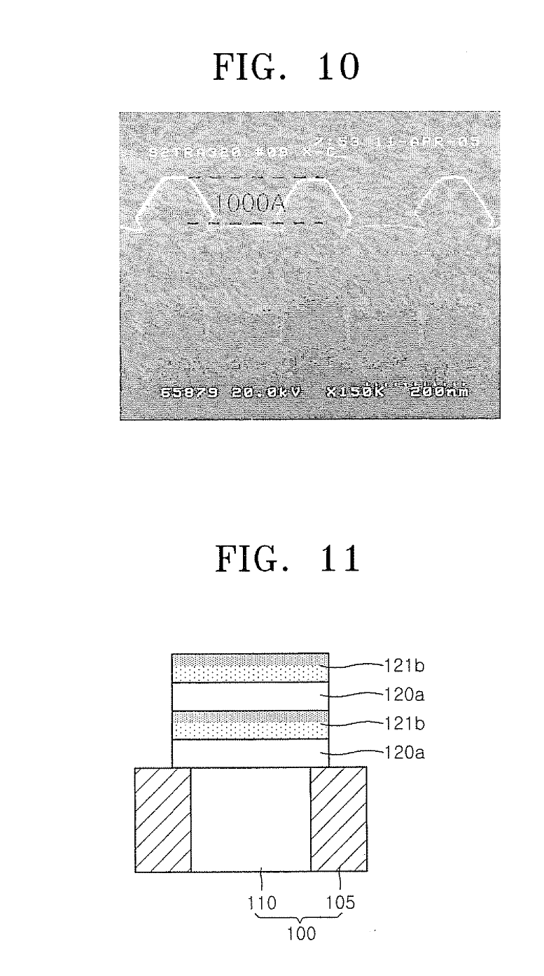

In certain embodiments of the present invention, the silicon epitaxial layers 120a and the silicon germanium epitaxial layers 120b may have the same thickness. In other embodiments, the silicon epitaxial layers 120a and the silicon germanium epitaxial layers 120b may have different thicknesses. For example, as shown in FIG. 9, the silicon germanium epitaxial layers 120b may be thinner than the silicon epitaxial layers 120a. In such embodiments, the epitaxial growth layer 120 has decreased thickness in the [111] orientation, which may improve the overall morphological uniformity of the epitaxial growth layer 120. Furthermore, the silicon epitaxial layer 120a that is formed on the surface of the silicon region 110 and the surface of the resultant structure further improves the uniformity. FIG. 10 is an SEM image of the epitaxial growth layer 120 obtained by growing the silicon epitaxial layers 120a to 200 Å and the silicon germanium epitaxial layers 120b to 100 Å, with the uppermost layer of epitaxial growth layer 120 being a silicon epitaxial layer 120a. The epitaxial growth layer 120 displays excellent uniformity compared with the structure shown in FIG. 7C.

In certain embodiments of the present invention, the silicon germanium epitaxial layer 120b may comprise a graded silicon germanium epitaxial layer, For example, as illustrated in FIG. 11, the a silicon germanium epitaxial layers 121b may have a distribution in which the germanium density gradually increases (graded distribution) as the thickness increases. In such embodiments, the germanium density may be less than 5% by atomic weight in the lower portion of the silicon germanium epitaxial layers 121b, but may be 5˜40% in the upper portion of the silicon germanium epitaxial layers 121b. The germanium density may increase either uniformly or non-uniformly in such graded silicon germanium layers. According to certain embodiments of the present invention, the graded silicon germanium epitaxial layers 121b may be formed by gradually increasing the quantity of the germanium source gas introduced into the growth chamber during the growth of each silicon germanium layer 121b.

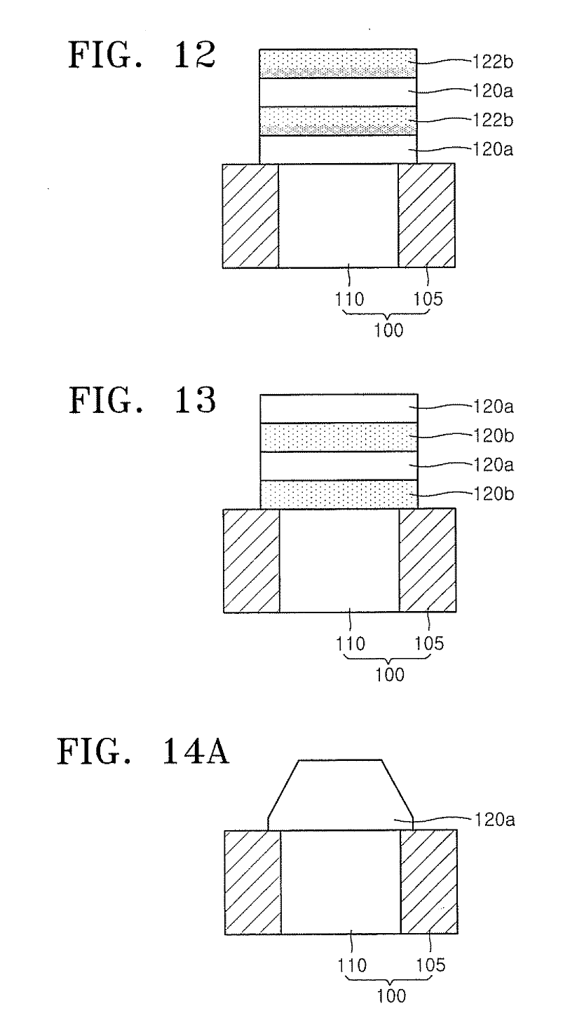

As shown in FIG. 12, in still other embodiments of the present invention the epitaxial growth layer may include graded silicon germanium epitaxial layers 122b in which the germanium density gradually decreases (retro-graded distribution) with increasing thickness. By way of example, the silicon germanium epitaxial layer 122b may have a germanium density of 5˜40% in its lower portion that is gradually reduced in the upper portion of the silicon germanium epitaxial layer 122b. Such retro-graded silicon germanium epitaxial layers 122b may be formed by gradually decreasing the quantity of the germanium source gas introduced during the growth of the layer. The silicon germanium epitaxial layers 121b and 122b in FIGS. 11 and 12 that have the graded germanium concentration may be formed to a thickness of, for example, about 20˜500 Å.

Although the silicon epitaxial layer 120a is first grown on the substrate 100 in the above embodiments, the silicon germanium epitaxial layer 120b may be formed first, followed by the silicon epitaxial layer 120a as shown in FIG. 13.

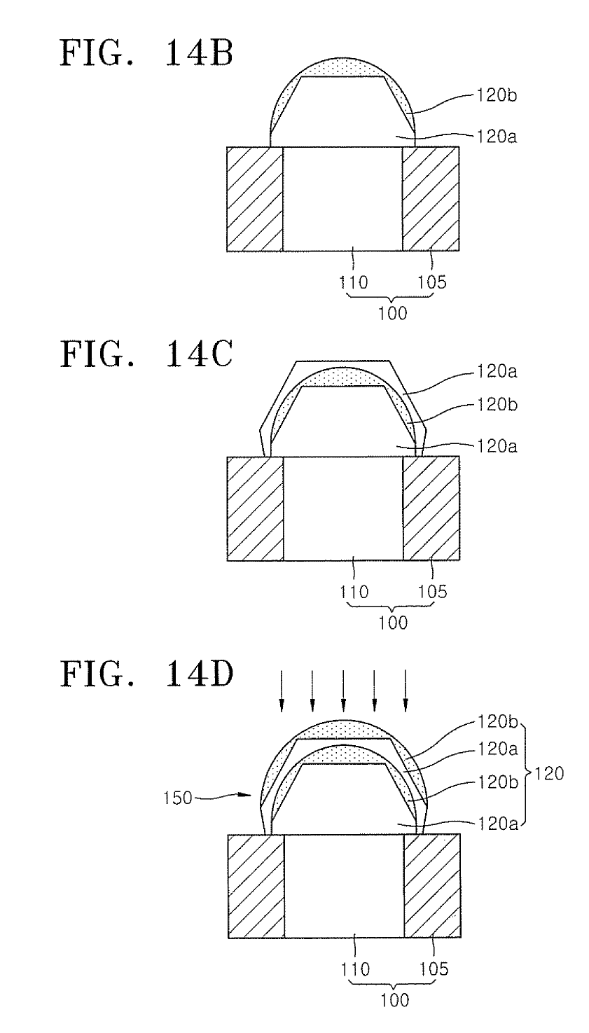

FIGS. 14A through 14D illustrate methods of manufacturing a semiconductor device having an epitaxial growth layer. Referring to FIG. 14A, a semiconductor substrate 100 is prepared. The semiconductor substrate 100 may include a silicon containing region 110 and an insulating region 105. The silicon containing region 110 may be, for example, an active region where a source or drain region will be formed, or a contact pad region that will contact the source or drain region. The insulating region 105 may, for example, be a device isolating layer or an interlayer insulating layer.

A silicon epitaxial layer 120a is grown on the semiconductor substrate 100. The silicon epitaxial layer 120a may be formed on a silicon substrate that contains a silicon component by supplying a raw gas that contains silicon atoms such as, for example, SiH₄, Si₂H₆, Si₃H₈, SiH₃Cl, Si₂H₂Cl₂ and/or SiHCl₃. The silicon epitaxial layer 120a may be formed, for example, by ultra high vacuum chemical vapor deposition in which the reactor pressure is maintained, for example, at about 10^{31 8}˜1 Torr while heating the semiconductor substrate 100 to about 400˜900° C. In other embodiments, the silicon epitaxial layer 120a may be formed by low pressure chemical vapor deposition by maintaining the reactor pressure at, for example, 0.1 mTorr or a normal atmosphere while heating the semiconductor substrate 100 to, for example, about 500˜1000° C. In still other embodiments, raw gas molecular beam deposition may be used by maintaining the reactor pressure at, for example, about 0.1˜200 mTorr while heating the semiconductor substrate 100 to, for example, about 400˜900° C. The thickness of the silicon epitaxial layer 120a may be selected based on, for example, a desired overall thickness for the multi-layered epitaxial growth layer and the number of individual layers that are to be included in the multi-layered epitaxial growth layer. In certain embodiments, the silicon epitaxial layer 120a may be, for example, about 10˜300 Å thick.

As shown in FIG. 14B, a silicon germanium epitaxial layer 120b is grown on the silicon epitaxial layer 120a. The silicon germanium epitaxial layer 120b may be formed, for example, by simultaneously supplying a raw gas that contains silicon atoms (e.g., SiH₄, Si₂H₆, Si₃H₈, SiH₃Cl, Si₂H₂Cl₂ and SiHCl₃ or a mixture of at least two of these gases), and a raw gas that contains germanium (e.g., GeH₄, Ge₂H₆, GeH₃Cl, Ge₂H₂Cl₂ and Ge₃HCl₃ or a mixture of at least two of these gases). In other embodiments, the silicon germanium epitaxial layer 120b may be formed by ultra high vacuum chemical vapor deposition, low pressure chemical vapor deposition or a raw gas molecular beam epitaxy, similar to the silicon epitaxial layer 120a. The raw gas that contains germanium may be supplied to allow the atomic germanium content within the silicon germanium epitaxial layer 120b to be about 0.1%˜40%. The thickness of the silicon germanium epitaxial layer 120b may be equal to or less than that of the silicon epitaxial layer 120a.

As discussed above, the silicon germanium epitaxial layer 120b tends to grow on the silicon epitaxial layer 120a in the [111] orientation. As a result, the overall epitaxial layer grows more in the vertical direction than it does in the lateral direction.

As shown in FIG. 14C, a second silicon epitaxial layer 120a is grown from the surface of the silicon germanium epitaxial layer 120b. The second silicon epitaxial layer 120a may be formed, for example, to have the same thickness, and by the same method, as the silicon epitaxial layer 120a already formed. Thus, the uneven surface due to the growth in the [111] orientation of the silicon germanium epitaxial layer 120b may be compensated.

As shown in FIG. 14D, another silicon germanium epitaxial layer 120b is grown on the silicon epitaxial layer 120a. The certain embodiments, the silicon germanium epitaxial layer 120b may be formed by the same method and to have the same thickness as the silicon germanium epitaxial layer 120b already formed, and may have the same germanium density.

The thickness and number of repetitions of the silicon epitaxial layer 120a and the silicon germanium epitaxial layer 120b may be adjusted based on, for example, the desired height of the epitaxial growth layer 120 (i.e., the height of the elevated source and drain regions). The uppermost layer may be the silicon germanium epitaxial layer 120b as in the embodiment of FIGS. 14A-14D, or may be a silicon epitaxial layer 120a as, for example, in the embodiment of FIG. 9.

The silicon epitaxial layer 120a and the silicon germanium epitaxial layer 120b form an active region where the source/drain will be formed later. Thereafter, an impurity (designated by arrows) is ion implanted into the active region, thereby forming the elevated source/drain region 150.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor device comprising:
a semiconductor substrate including a silicon region; and
an epitaxial growth layer on the silicon region, the epitaxial growth layer comprising a first silicon epitaxial layer and a second silicon epitaxial layer that are alternatively stacked with a first epitaxial layer containing a germanium component and a second epitaxial layer containing a germanium component.

2. The semiconductor device of claim 1, wherein the first epitaxial layer containing a germanium component comprises a first silicon germanium epitaxial layer, and wherein the second epitaxial layer containing a germanium component comprises a second silicon germanium epitaxial layer.

3. The semiconductor device of claim 2, wherein the epitaxial growth layer comprises an elevated source/drain region.

4. The semiconductor device of claim 2, wherein a combined thickness of the first and second silicon germanium epitaxial layers is less than a combined thickness of the first and second silicon epitaxial layers.

5. The semiconductor device of claim 2, wherein a combined thickness of the first and second silicon germanium epitaxial layers is approximately equal to a combined thickness of the first and second silicon epitaxial layers.

6. The semiconductor device of claim 2, wherein the thickness of each of the first and second silicon epitaxial layers and the first and second silicon germanium epitaxial layers is between about 10˜300 Angstroms.

7. The semiconductor device of claim 2, wherein the atomic germanium density of at least one of the first or second silicon germanium epitaxial layers is about 2˜40%.

8. The semiconductor device of claim 2, wherein at least one of the first or second silicon germanium epitaxial layers is a graded silicon germanium epitaxial layer.

9. The semiconductor device of claim 8, wherein the thickness of the graded silicon germanium epitaxial layer is between about 20˜500 Angstroms.

10. The semiconductor device of claim 8, wherein a germanium density of the graded silicon germanium epitaxial layer increases with the thickness of the graded silicon germanium epitaxial layer.

11. The semiconductor device of claim 8, wherein a germanium density of the graded silicon germanium epitaxial layer decreases with the thickness of the graded silicon germanium epitaxial layer.

12. The semiconductor device of claim 2, wherein the first silicon epitaxial layer comprises a lower surface of the epitaxial growth layer, and wherein an uppermost surface of the epitaxial growth layer is a silicon epitaxial layer.

13. A semiconductor device comprising:
a semiconductor substrate having a top surface;
an epitaxial layer including a first silicon epitaxial layer on the semiconductor substrate, a first silicon germanium epitaxial layer on the first silicon epitaxial layer, and a second silicon epitaxial layer on the first silicon germanium epitaxial layer; and
first and second source/drain regions in the epitaxial layer.

14. The semiconductor device of claim 13, wherein the epitaxial layer further includes a second silicon germanium epitaxial layer either between the semiconductor substrate and the first silicon epitaxial layer or on the second silicon epitaxial layer.

15. The semiconductor device of claim 13, wherein the first silicon epitaxial layer is on the top surface of the semiconductor substrate, the first silicon germanium epitaxial layer is on the first silicon epitaxial layer, the second silicon epitaxial layer is on the first silicon germanium epitaxial layer, and the second silicon germanium epitaxial layer is on the second silicon epitaxial layer.

16. The semiconductor device of claim 14, wherein a combined thickness of the first and second silicon germanium epitaxial layers is less than a combined thickness of the first and second silicon epitaxial layers.

17. The semiconductor device of claim 13, wherein the first silicon epitaxial layer and the first silicon germanium epitaxial layer each have a thickness of between about 10˜300 Angstroms.

18. The semiconductor device of claim 13, wherein the atomic germanium density of the first silicon germanium epitaxial layer is about 2˜40%.

19. The semiconductor device of claim 13, wherein the first silicon germanium epitaxial layer is a graded silicon germanium epitaxial layer.

20. The semiconductor device of claim 19, wherein the first silicon germanium epitaxial layer has a thickness of between about 20˜500 Angstroms.

21. A method of manufacturing a semiconductor device, comprising:
forming a first silicon epitaxial layer on a semiconductor substrate;
forming a first epitaxial layer containing a germanium component on the first silicon epitaxial layer;
forming a second silicon epitaxial layer on the first epitaxial layer containing a germanium component, wherein the first silicon epitaxial layer, the first epitaxial layer containing a germanium component and the second silicon epitaxial layer comprise an epitaxial growth layer; and
forming a source/drain region in the epitaxial growth layer.

22. The method of claim 21, further comprising forming a second epitaxial layer containing a germanium component that is part of the epitaxial growth layer between the semiconductor substrate and the first silicon epitaxial layer or on the second silicon epitaxial layer.

23. The method of claim 21, wherein the first and second silicon epitaxial layers are formed using SiH₄, Si₂H₆, Si₃H₈, SiH₃Cl, Si₂H₂Cl₂ and/or SiHCl₃ as a silicon source gas.

24. The method of claim 22, wherein the first and second epitaxial layers containing a germanium component are formed using SiH₄, Si₂H₆, Si₃H₈, SiH₃Cl, Si₂H₂Cl₂ and/or SiHCl₃ as a silicon source gas and using GeH₄, Ge₂H₆, GeH₃Cl, Ge₂H₂Cl₂ and/or Ge₃HCl₃ as a germanium source gas.

25. The method of claim 24, wherein the atomic germanium density of the first and second epitaxial layers containing a germanium component is between about 2˜40%.

26. The method of claim 22, wherein the first and second epitaxial layers containing a germanium component comprise graded layers having a gradually increasing germanium density.

27. The method of claim 22, wherein the first and second epitaxial layers containing a germanium component comprise graded layers having a gradually decreasing germanium density.

28. The method of claim 22, wherein at least one of the first and second silicon epitaxial layers or one of the first and second epitaxial layers containing the germanium component is formed by ultra high vacuum chemical vapor deposition while maintaining a reactor pressure between about 10⁻⁸˜1 Torr and heating the semiconductor substrate to between about 400˜900° C.

29. The method of claim 22, wherein at least one of the first and second silicon epitaxial layers or one of the first and second epitaxial layers containing the germanium component is formed by low pressure chemical vapor deposition while maintaining a reactor pressure between about 1 mTorr or a normal pressure and heating the semiconductor substrate to between about 500˜1000° C.

30. The method of claim 22, wherein at least one of the first and second silicon epitaxial layers or one of the epitaxial layers containing the germanium component is formed by raw gas molecular beam deposition while maintaining a reactor pressure between about 0.1˜200 mTorr and heating the semiconductor substrate to between about 400˜900° C.
